(19) United States
(12) Patent Application Publication
(10) Pub. No.: US 2017/0222641 A1
(43) Pub. Date: Aug. 3, 2017

(54) DYNAMIC IGBT GATE DRIVE TO REDUCE SWITCHING LOSS

(71) Applicant: Ford Global Technologies, LLC, Dearborn, MI (US)

(72) Inventors: Ke Zou, Canton, MI (US); Chingchi Chen, Ann Arbor, MI (US)

(21) Appl. No.: 15/010,825

(22) Filed: Jan. 29, 2016

(51) Int. Cl. H03K 17/16; H02M 3/07; H03K 17/567; B60L 11/18; H02P 27/06; H02M 7/217; H02M 1/08

(52) U.S. Cl. CPC H03K 17/168; H02M 7/217; H02M 3/07; H02M 1/08; B60L 11/1803; H02P 27/06; H03K 17/567; H02M 2001/0054

(57) ABSTRACT

An inverter includes an N-channel IGBT, with a freewheeling diode, coupled to a phase of an electric machine, and has a MOSFET coupling a local voltage with a gate of the IGBT and configured to transition from saturation to linear operation as a current flow direction through the diode switches from positive to negative while the IGBT initiates a current through the electric machine.

### TECHNICAL FIELD

This application is generally related to control of a gate voltage to an IGBT in a hybrid-electric powertrain.

### BACKGROUND

Electrified vehicles including hybrid-electric vehicles (HEVs) and battery electric vehicles (BEVs) rely on a traction battery to provide power to a traction motor for propulsion and a power inverter therebetween to convert direct current (DC) power to alternating current (AC) power. The typical AC traction motor is a 3-phase motor that may be powered by 3 sinusoidal signals each driven with 120 degrees phase separation. The traction battery is configured to operate in a particular voltage range. The terminal voltage of a typical traction battery is over 100 Volts DC and the traction battery is alternatively referred to as a high-voltage battery. However, improved performance of electric machines may be achieved by operating in a different voltage range, typically at higher voltages than the traction battery. Many electrified vehicles include a DC-DC converter also referred to as a variable voltage converter (VVC) to convert the voltage of the traction battery to an operational voltage level of the electric machine. The electric machine that may include a traction motor may require a high voltage and high current. Due to the voltage, current and switching requirements, an Insulated Gate Bipolar junction Transistor (IGBT) is typically used to generate the signals in the power inverter and the VVC.

### SUMMARY

A vehicle comprises an inverter including an N-channel IGBT, with a freewheeling diode, coupled to a phase of an electric machine, and having a MOSFET coupling a local voltage with a gate of the IGBT and configured to transition from saturation to linear operation as a current flow direction through the diode switches from positive to negative while the IGBT initiates a current through the electric machine.

A vehicle DC-DC converter comprises an inductor, an N-channel charge IGBT with a freewheeling diode coupled between a terminal of the inductor and a local ground, and a charge MOSFET coupling a local voltage with a gate of the charge IGBT, and configured to transition from saturation to linear operation as a current flow direction in the diode switches from positive to negative while the IGBT initiates a current through the inductor.

A power electronics module for a vehicle comprises an N-channel IGBT having an emitter, gate, and collector, a freewheeling diode coupled parallel with the IGBT, and a MOSFET coupling a local voltage with the IGBT gate and configured to transition from saturation to linear operation as a direction of current flowing through the diode reverses from positive to negative while the IGBT turns on.

### BRIEF DESCRIPTION OF THE DRAWINGS

FIG. 1 is a diagram of a hybrid vehicle illustrating typical drivetrain and energy storage components with a power inverter therebetween.

FIG. 2 is a schematic of a vehicular variable voltage converter.

FIG. 3 is a schematic of a vehicular electric motor inverter.

FIG. 4 is a graphical representation of IGBT and freewheeling diode operation with respect to time.

FIG. 5 is a graphical representation of a MOSFET drain current with respect to time at a plurality of gate voltages.

FIG. 6 is a graphical representation of diode voltage with respect to IGBT collector current.

FIG. 7 is a graphical representation of diode voltage with respect to IGBT gate current.

FIG. 8 is a graphical representation of MOSFET drain current with respect to IGBT gate voltage.

FIG. 9 is a schematic diagram of a MOSFET coupled with an IGBT to control the gate voltage of the IGBT.

FIG. 10 is a graphical representation of MOSFET drain current with respect to IGBT gate voltage.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Insulated Gate Bipolar junction Transistors (IGBTs) and flyback or freewheeling diodes are widely used in a variety of industrial applications, such as inverters to convert between AC and DC power to flow and convert DC power to an AC electric motor and to flow and convert AC power from a generator to a DC battery. Operation of an IGBT is controlled by a gate voltage supplied by a gate driver. Conventional gate drivers are typically based on a voltage, greater than a threshold voltage, applied to an IGBT gate with a current limiting resistor, which consists of a switchable voltage source and gate resistor. A low gate resistance would provide a fast switching speed and low switching loss, but also result in greater stresses on the semiconductor devices, for example, over-voltage stress. Therefore, a gate resistance is selected to seek a compromise between switching loss, switching delay, and stress on the devices.

Some disadvantages associated with conventional gate drivers for IGBT turn-on include limited control of switching delay time, current slope and voltage slope such that optimization switching losses are limited. Another disadvantage is that a gate resistance is typically selected based on worst case operating condition thus introducing excessive switching losses under normal operating conditions. For example, at high DC bus voltages, a gate resistance is selected based on a change in current with respect to time (di/dt) in order to avoid excessive diode voltage overshoot during diode fly-back of the load. However, at low DC bus voltages the use of the gate resistance selected to protect for high bus voltages introduces excessive switching losses as a switching speed is then reduced by the gate resistance even though diode over-voltage is below a critical threshold.

A smart gate driving strategy may be necessary to achieve optimal switching performance for the whole switching trajectory and over all the operating ranges. Here, a matched MOSFET/IGBT combination is shown to reduce switching losses and limit flyback diode overshoot. The MOSFET is matched with the IGBT such that a multi-step gate driving profile is composed of a MOSFET saturation region followed by a MOSFET linear region. Operation in the saturation region reduces the turn-on delay time, as well as increases the IGBT switching speed and reduces IGBT switching losses. The linear region slows down the IGBT switching speed to avoid the excessive voltage overshoot across the associated freewheeling diode. The timing for each pulse stage is selected based on the MOSFET characteristics and matched with the associated IGBT operating conditions, e.g., IGBT gate voltage (Vge) and IGBT transconductance associated with the Vge, to realize the optimal switching performance over the whole operating range.

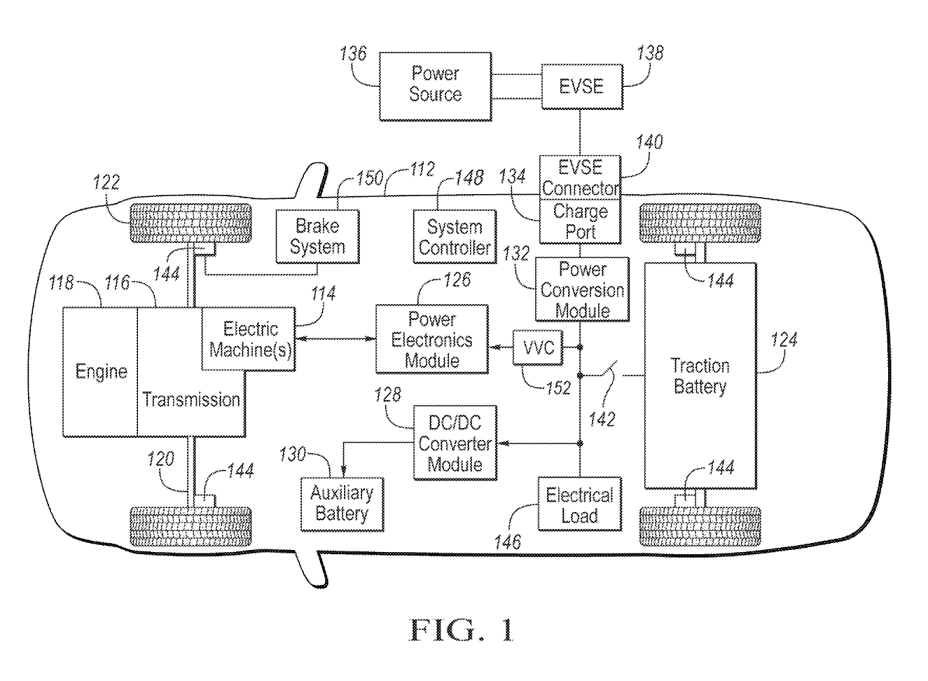

FIG. 1 depicts an electrified vehicle 112 that may be referred to as a plug-in hybrid-electric vehicle (PHEV). A plug-in hybrid-electric vehicle 112 may comprise one or more electric machines 114 mechanically coupled to a hybrid transmission 116. The electric machines 114 may be capable of operating as a motor or a generator. In addition, the hybrid transmission 116 is mechanically coupled to an engine 118. The hybrid transmission 116 is also mechanically coupled to a drive shaft 120 that is mechanically coupled to the wheels 122. The electric machines 114 can provide propulsion and deceleration capability when the engine 118 is turned on or off. The electric machines 114 may also act as generators and can provide fuel economy benefits by recovering energy that would normally be lost as heat in a friction braking system. The electric machines 114 may also reduce vehicle emissions by allowing the engine 118 to operate at more efficient speeds and allowing the hybrid-electric vehicle 112 to be operated in electric mode with the engine 118 off under certain conditions. An electrified vehicle 112 may also be a battery electric vehicle (BEV). In a BEV configuration, the engine 118 may not be present. In other configurations, the electrified vehicle 112 may be a full hybrid-electric vehicle (FHEV) without plug-in capability.

A traction battery or battery pack 124 stores energy that can be used by the electric machines 114. The vehicle battery pack 124 may provide a high voltage direct current (DC) output. The traction battery 124 may be electrically coupled to one or more power electronics modules 126. One or more contactors 142 may isolate the traction battery 124 from other components when opened and connect the traction battery 124 to other components when closed. The power electronics module 126 is also electrically coupled to the electric machines 114 and provides the ability to bi-directionally transfer energy between the traction battery 124 and the electric machines 114. For example, a traction battery 124 may provide a DC voltage while the electric machines 114 may operate with a three-phase alternating current (AC) to function. The power electronics module 126 may convert the DC voltage to a three-phase AC current to operate the electric machines 114. In a regenerative mode, the power electronics module 126 may convert the three-phase AC current from the electric machines 114 acting as generators to the DC voltage compatible with the traction battery 124.

The vehicle 112 may include a variable-voltage converter (VVC) 152 electrically coupled between the traction battery 124 and the power electronics module 126. The VVC 152 may be a DC/DC boost converter configured to increase or boost the voltage provided by the traction battery 124. By increasing the voltage, current requirements may be decreased leading to a reduction in wiring size for the power electronics module 126 and the electric machines 114. Further, the electric machines 114 may be operated with better efficiency and lower losses.

In addition to providing energy for propulsion, the traction battery 124 may provide energy for other vehicle electrical systems. The vehicle 112 may include a DC/DC converter module 128 that converts the high voltage DC output of the traction battery 124 to a low voltage DC supply that is compatible with low-voltage vehicle loads. An output of the DC/DC converter module 128 may be electrically coupled to an auxiliary battery 130 (e.g., 12V battery) for charging the auxiliary battery 130. The low-voltage systems may be electrically coupled to the auxiliary battery 130. One or more electrical loads 146 may be coupled to the high-voltage bus. The electrical loads 146 may have an associated controller that operates and controls the electrical loads 146 when appropriate. Examples of electrical loads 146 may be a fan, an electric heating element and/or an air-conditioning compressor.

The electrified vehicle 112 may be configured to recharge the traction battery 124 from an external power source 136. The external power source 136 may be a connection to an electrical outlet. The external power source 136 may be electrically coupled to a charger or electric vehicle supply equipment (EVSE) 138. The external power source 136 may be an electrical power distribution network or grid as provided by an electric utility company. The EVSE 138 may provide circuitry and controls to regulate and manage the transfer of energy between the power source 136 and the vehicle 112. The external power source 136 may provide DC or AC electric power to the EVSE 138. The EVSE 138 may have a charge connector 140 for plugging into a charge port 134 of the vehicle 112. The charge port 134 may be any type of port configured to transfer power from the EVSE 138 to the vehicle 112. The charge port 134 may be electrically coupled to a charger or on-board power conversion module 132. The power conversion module 132 may condition the power supplied from the EVSE 138 to provide the proper voltage and current levels to the traction battery 124. The power conversion module 132 may interface with the EVSE 138 to coordinate the delivery of power to the vehicle 112. The EVSE connector 140 may have pins that mate with corresponding recesses of the charge port 134. Alternatively, various components described as being electrically coupled or connected may transfer power using a wireless inductive coupling.

One or more wheel brakes 144 may be provided for decelerating the vehicle 112 and preventing motion of the vehicle 112. The wheel brakes 144 may be hydraulically actuated, electrically actuated, or some combination thereof. The wheel brakes 144 may be a part of a brake system 150. The brake system 150 may include other components to operate the wheel brakes 144. For simplicity, the figure depicts a single connection between the brake system 150 and one of the wheel brakes 144. A connection between the brake system 150 and the other wheel brakes 144 is implied. The brake system 150 may include a controller to monitor and coordinate the brake system 150. The brake system 150 may monitor the brake components and control the wheel brakes 144 for vehicle deceleration. The brake system 150 may respond to driver commands and may also operate autonomously to implement features such as stability control. The controller of the brake system 150 may implement a method of applying a requested brake force when requested by another controller or sub-function.

Electronic modules in the vehicle 112 may communicate via one or more vehicle networks. The vehicle network may include a plurality of channels for communication. One channel of the vehicle network may be a serial bus such as a Controller Area Network (CAN). One of the channels of the vehicle network may include an Ethernet network defined by Institute of Electrical and Electronics Engineers (IEEE) 802 family of standards. Additional channels of the vehicle network may include discrete connections between modules and may include power signals from the auxiliary battery 130. Different signals may be transferred over different channels of the vehicle network. For example, video signals may be transferred over a high-speed channel (e.g., Ethernet) while control signals may be transferred over CAN or discrete signals. The vehicle network may include any hardware and software components that aid in transferring signals and data between modules. The vehicle network is not shown in FIG. 1 but it may be implied that the vehicle network may connect to any electronic module that is present in the vehicle 112. A vehicle system controller (VSC) 148 may be present to coordinate the operation of the various components.

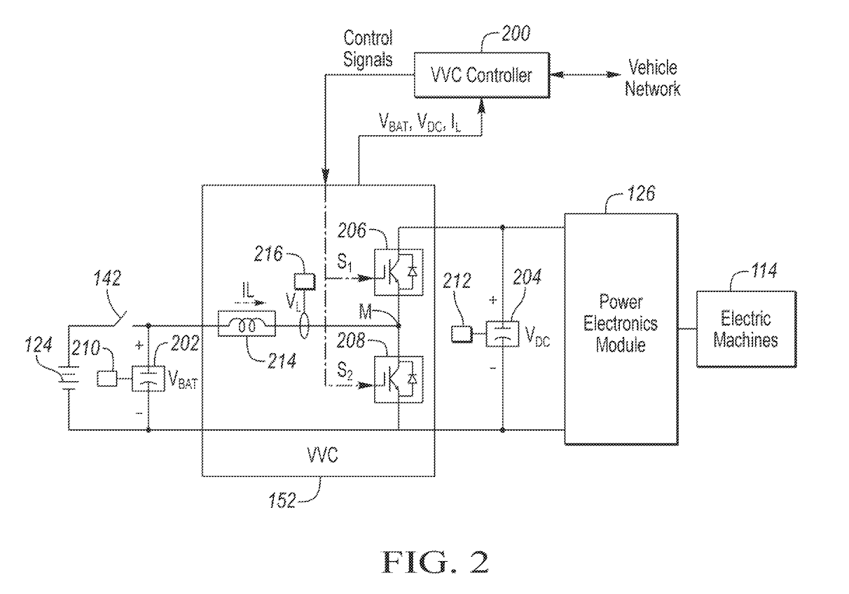

FIG. 2 depicts a diagram of a VVC 152 that is configured as a boost converter. The VVC 152 may include input terminals that may be coupled to terminals of the traction battery 124 through the contactors 142. The VVC 152 may include output terminals coupled to terminals of the power electronics module 126. The VVC 152 may be operated in a boost mode to cause a voltage at the output terminals to be greater than a voltage at the input terminals. The VVC 152 may be operated in a buck mode to cause a voltage at the output terminals to be less than a voltage at the input terminals. The VVC 152 may be operated in a bypass mode to cause a voltage at the output terminals to be approximately equal to a voltage at the input terminals. The vehicle 112 may include a VVC controller 200 that monitors and controls electrical parameters (e.g., voltage and current) at various locations within the VVC 152. In some configurations, the VVC controller 200 may be included as part of the VVC 152. The VVC controller 200 may determine an output voltage reference, V_{dc}*. The VVC controller 200 may determine, based on the electrical parameters and the voltage reference, V_{dc}*, a control signal sufficient to cause the VVC 152 to achieve the desired output voltage. In some configurations, the control signal may be implemented as a pulse-width modulated (PWM) signal in which a duty cycle of the PWM signal is varied. The control signal may be operated at a predetermined switching frequency. The VVC controller 200 may command the VVC 152 to provide the desired output voltage using the control signal. The particular control signal at which the VVC 152 is operated may be directly related to the amount of voltage boost to be provided by the VVC 152.

The output voltage of the VVC 152 may be controlled to achieve a desired reference voltage. In some configurations, the VVC 152 may be a boost converter. In a boost converter configuration in which the VVC controller 200 controls the duty cycle, the ideal relationship between the input voltage Vᵢₙ and the output voltage Vₒᵤₜ and the duty cycle D may be illustrated using the following equation:

$${V}_{out} = \frac{{V}_{in}}{( 1 - D )} \qquad 1 )$$

The desired duty cycle, D, may be determined by measuring the input voltage (e.g., traction battery voltage) and setting the output voltage to the reference voltage. The VVC 152 may be a buck converter that reduces the voltage from input to output. In a buck configuration, a different expression relating the input and output voltage to the duty cycle may be derived. In some configurations, the VVC 152 may be a buck-boost converter that may increase or decrease the input voltage. The control strategy described herein is not limited to a particular variable voltage converter topology.

With reference to FIG. 2, the VVC 152 may boost or “step up” the voltage potential of the electrical power provided by the traction battery 124. The traction battery 124 may provide high voltage (HV) DC power. High voltage is any voltage greater than 100 Volts DC or 100 Volts AC. In some configurations, the traction battery 124 may provide a voltage between 150 and 400 Volts. The contactor 142 may be electrically coupled in series between the traction battery 124 and the VVC 152. When the contactor 142 is closed, the HV DC power may be transferred from the traction battery 124 to the VVC 152. An input capacitor 202 may be electrically coupled in parallel to the traction battery 124. The input capacitor 202 may stabilize the bus voltage and reduce any voltage and current ripple. The VVC 152 may receive the HV DC power and boost or “step up” the voltage potential of the input voltage according to the duty cycle.

An output capacitor 204 may be electrically coupled between the output terminals of the VVC 152. The output capacitor 204 may stabilize the bus voltage and reduce voltage and current ripple at the output of the VVC 152.

Further with reference to FIG. 2, the VVC 152 may include a first switching device 206 and a second switching device 208 for boosting an input voltage to provide the boosted output voltage. The switching devices 206, 208 may be configured to selectively flow a current to an electrical load (e.g., power electronics module 126 and electric machines 114). Each switching device 206, 208 may be individually controlled by a gate drive circuit (not shown) of the VVC controller 200 and may include any type of controllable switch (e.g., an insulated gate bipolar transistor (IGBT) or field-effect transistor (FET)). The gate drive circuit may provide electrical signals to each of the switching devices 206, 208 that are based on the control signal (e.g., duty cycle of PWM control signal). A diode may be coupled across each of the switching devices 206, 208. The switching devices 206, 208 may each have an associated switching loss. The switching losses are those power losses that occur during state changes of the switching device (e.g., on/off and off/on transitions). The switching losses may be quantified by the current flowing through and the voltage across the switching device 206, 208 during the transition. The switching devices may also have associated conduction losses that occur when the device is switched on.

The vehicle system may include sensors for measuring electrical parameters of the VVC 152. A first voltage sensor 210 may be configured to measure the input voltage, (e.g., voltage of the battery 124), and provide a corresponding input signal (V_{bat}) to the VVC controller 200. In one or more embodiments, the first voltage sensor 210 may measure the voltage across the input capacitor 202, which corresponds to the battery voltage. A second voltage sensor 212 may measure the output voltage of the VVC 152 and provide a corresponding input signal (V_{dc}) to the VVC controller 200. In one or more embodiments, the second voltage sensor 212 may measure the voltage across the output capacitor 204, which corresponds to the DC bus voltage. The first voltage sensor 210 and the second voltage sensor 212 may include circuitry to scale the voltages to a level appropriate for the VVC controller 200. The VVC controller 200 may include circuitry to filter and digitize the signals from the first voltage sensor 210 and the second voltage sensor 212.

An input inductor 214 may be electrically coupled in series between the traction battery 124 and the switching devices 206, 208. The input inductor 214 may alternate between storing and releasing energy in the VVC 152 to enable the providing of the variable voltages and currents as VVC 152 output, and the achieving of the desired voltage boost. A current sensor 216 may measure the input current through the input inductor 214 and provide a corresponding current signal (I_{L}) to the VVC controller 200. The input current through the input inductor 214 may be a result of the voltage difference between the input and the output voltage of the VVC 152, the conducting time of the switching devices 206, 208, and the inductance L of the input inductor 214. The VVC controller 200 may include circuitry to scale, filter, and digitize the signal from the current sensor 216.

The VVC controller 200 may be programmed to control the output voltage of the VVC 152. The VVC controller 200 may receive input from the VVC 152 and other controllers via the vehicle network, and determine the control signals. The VVC controller 200 may monitor the input signals (V_{bat}, V_{dc}, I_{L}, V_{dc}*) to determine the control signals. For example, the VVC controller 200 may provide control signals to the gate drive circuit that correspond to a duty cycle command. The gate drive circuit may then control each switching device 206, 208 based on the duty cycle command.

The control signals to the VVC 152 may be configured to drive the switching devices 206, 208 at a particular switching frequency. Within each cycle of the switching frequency, the switching devices 206, 208 may be operated at the specified duty cycle. The duty cycle defines the amount of time that the switching devices 206, 208 are in an on-state and an off-state. For example, a duty cycle of 100% may operate the switching devices 206, 208 in a continuous on-state with no turn off. A duty cycle of 0% may operate the switching devices 206, 208 in a continuous off-state with no turn on. A duty cycle of 50% may operate the switching devices 206, 208 in an on-state for half of the cycle and in an off-state for half of the cycle. The control signals for the two switches 206, 208 may be complementary. That is, the control signal sent to one of the switching devices (e.g., 206) may be an inverted version of the control signal sent to the other switching device (e.g., 208).

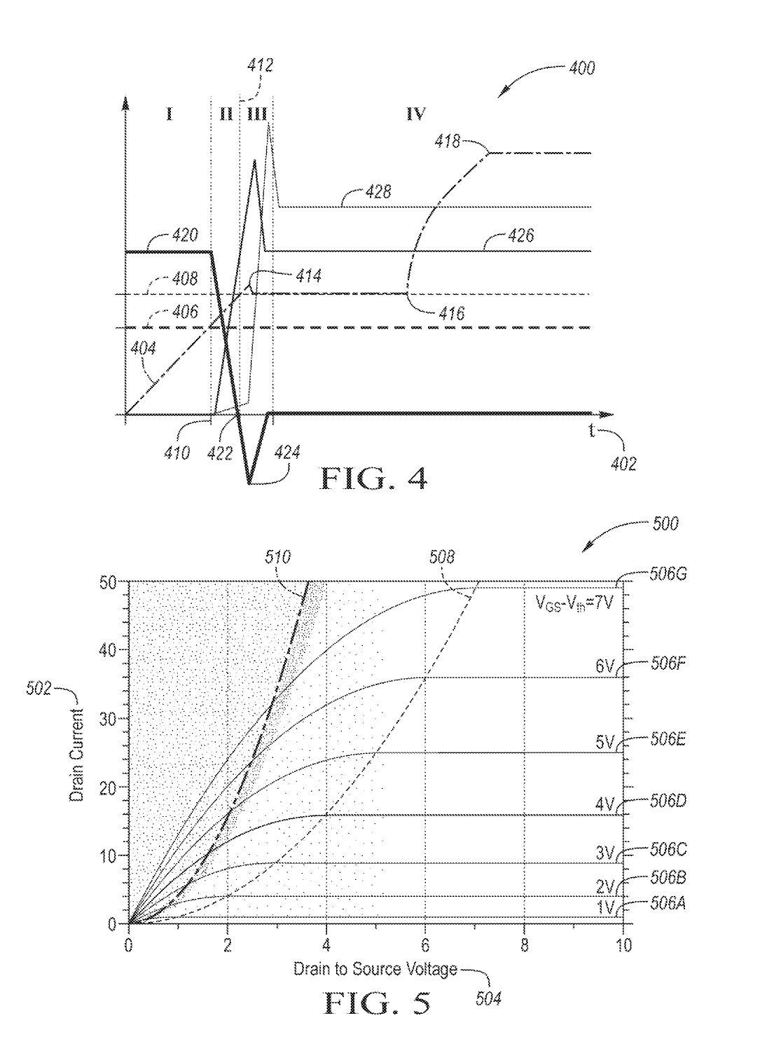

The current that is controlled by the switching devices 206, 208 may include a ripple component that has a magnitude that varies with a magnitude of the current, and the duty cycle and switching frequency of the switching devices 206, 208. Relative to the input current, the worst case ripple current magnitude occurs during relatively high input current conditions. When the duty cycle is fixed, an increase in the inductor current causes an increase in magnitude of the ripple current as illustrated in FIG. 4. The magnitude of the ripple current is also related to the duty cycle. The highest magnitude ripple current occurs when the duty cycle equals 50%. The general relationship between the inductor ripple current magnitude and the duty cycle may be as shown in FIG. 5. Based on these facts, it may be beneficial to implement measures to reduce the ripple current magnitude under high current and mid-range duty cycle conditions.

When designing the VVC 152, the switching frequency and the inductance value of the inductor 214 may be selected to satisfy a maximum allowable ripple current magnitude. The ripple component may be a periodic variation that appears on a DC signal. The ripple component may be defined by a ripple component magnitude and a ripple component frequency. The ripple component may have harmonics that are in an audible frequency range that may add to the noise signature of the vehicle. Further, the ripple component may cause difficulties with accurately controlling devices fed by the source. During switching transients, the switching devices 206, 208 may turn off at the maximum inductor current (DC current plus ripple current) which may cause large voltage spike across the switching devices 206, 208. Because of size and cost constraints, the inductance value may be selected based on the conducted current. In general, as current increases the inductance may decrease due to saturation.

The switching frequency may be selected to limit a magnitude of the ripple current component under worst case scenarios (e.g., highest input current and/or duty cycle close to 50% conditions). The switching frequency of the switching devices 206, 208 may be selected to be a frequency (e.g., 10 kHz) that is greater than a switching frequency of the motor/generator inverter (e.g., 5 kHz) that is coupled to an output of the VVC 152. In some applications, the switching frequency of the VVC 152 may be selected to be a predetermined fixed frequency. The predetermined fixed frequency is generally selected to satisfy noise and ripple current specifications. However, the choice of the predetermined fixed frequency may not provide best performance over all operating ranges of the VVC 152. The predetermined fixed frequency may provide best results at a particular set of operating conditions, but may be a compromise at other operating conditions.

Increasing the switching frequency may decrease the ripple current magnitude and lower voltage stress across the switching devices 206, 208, but may lead to higher switching losses. While the switching frequency may be selected for worst case ripple conditions, the VVC 152 may only operate under the worst case ripple conditions for a small percentage of the total operating time. This may lead to unnecessarily high switching losses that may lower fuel economy. In addition, the fixed switching frequency may concentrate the noise spectrum in a very narrow range. The increased noise density in this narrow range may result in noticeable noise, vibration, and harshness (NVH) issues.

The VVC controller 200 may be programmed to vary the switching frequency of the switching devices 206, 208 based on the duty cycle and the input current. The variation in switching frequency may improve fuel economy by reducing switching losses and reduce NVH issues while maintaining ripple current targets under worst case operating conditions.

During relatively high current conditions, the switching devices 206, 208 may experience increased voltage stress. At a maximum operating current of the VVC 152, it may be desired to select a relatively high switching frequency that reduces the ripple component magnitude with a reasonable level of switching losses. The switching frequency may be selected based on the input current magnitude such that as the input current magnitude increases, the switching frequency increases. The switching frequency may be increased up to a predetermined maximum switching frequency. The predetermined maximum switching frequency may be a level that provides a compromise between lower ripple component magnitudes and higher switching losses. The switching frequency may be changed in discrete steps or continuously over the operating current range.

The VVC controller 200 may be programmed to reduce the switching frequency in response to the current input being less than a predetermined maximum current. The predetermined maximum current may be a maximum operating current of the VVC 152. The change in the switching frequency may be based on the magnitude of the current input to the switching devices 206, 208. When the current is greater than the predetermined maximum current, the switching frequency may be set to a predetermined maximum switching frequency. As the current decreases, the magnitude of the ripple component decreases. By operating at lower switching frequencies as the current decreases, switching losses are reduced. The switching frequency may be varied based on the power input to the switching devices. As the input power is a function of the input current and the battery voltage, the input power and input current may be used in a similar manner.

Since the ripple current is also affected by the duty cycle, the switching frequency may be varied based on the duty cycle. The duty cycle may be determined based on a ratio of the input voltage to the output voltage. As such, the switching frequency may also be varied based on the ratio between the input voltage and the output voltage. When the duty cycle is near 50%, the predicted ripple current magnitude is a maximum value and the switching frequency may be set to the predetermined maximum frequency. The predetermined maximum frequency may be a maximum switching frequency value that is selected to minimize the ripple current magnitude. The switching frequency may be changed in discrete steps or continuously over the duty cycle range.

The VVC controller 200 may be programmed to reduce the switching frequency from the predetermined maximum frequency in response to a magnitude of a difference between the duty cycle and the duty cycle value (e.g, 50%) at which the predicted ripple component magnitude is a maximum. When the magnitude of the difference is less than a threshold, the switching frequency may be set to the predetermined frequency. When the magnitude of the difference decreases, the switching frequency may be increased toward the predetermined maximum frequency to reduce the ripple component magnitude. When the magnitude of the difference is less than a threshold, the switching frequency may be set to the predetermined maximum frequency.

The switching frequency may be limited to be between the predetermined maximum frequency and a predetermined minimum frequency. The predetermined minimum frequency may be a frequency level that is greater than a predetermined switching frequency of the power electronic module 126 that is coupled to an output of the voltage converter 152.

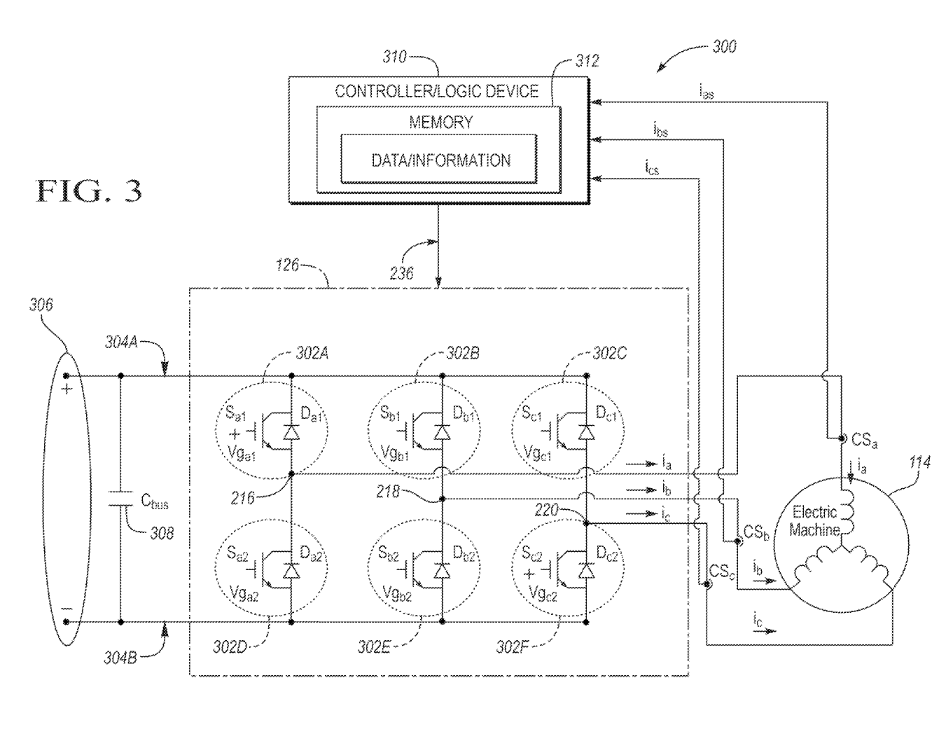

With reference to FIG. 3, a system 300 is provided for controlling a power electronics module (PEM) 126. The PEM 126 of FIG. 3 is shown to include a plurality of switches 302 (e.g., IGBTs) configured to collectively operate as an inverter with first, second, and third phase legs 316, 318, 320. While the inverter is shown as a three-phase converter, the inverter may include additional phase legs. For example, the inverter may be a four-phase converter, a five-phase converter, a six-phase converter, etc. In addition, the PEM 126 may include multiple converters with each inverter in the PEM 126 including three or more phase legs. For example, the system 300 may control two or more inverters in the PEM 126. The PEM 126 may further include a DC to DC converter having high power switches (e.g., IGBTs) to convert a power electronics module input voltage to a power electronics module output voltage via boost, buck or a combination thereof.

As shown in FIG. 3, the inverter may be a DC-to-AC converter. In operation, the DC-to-AC converter receives DC power from a DC power link 306 through a DC bus 304 and converts the DC power to AC power. The AC power is transmitted via the phase currents ia, ib, and ic to drive an AC machine also referred to as an electric machine 114, such as a three-phase permanent-magnet synchronous motor (PMSM) as depicted in FIG. 3. In such an example, the DC power link 306 may include a DC storage battery to provide DC power to the DC bus 304. In another example, the inverter may operate as an AC-to-DC converter that converts AC power from the AC machine 114 (e.g., generator) to DC power, which the DC bus 304 can provide to the DC power link 306. Furthermore, the system 300 may control the PEM 126 in other power electronic topologies.

With continuing reference to FIG. 3, each of the phase legs 316, 318, 320 in the inverter includes power switches 302, which may be implemented by various types of controllable switches. In one embodiment, each power switch 302 may include a diode and a transistor, (e.g., an IGBT). The diodes of FIG. 3 are labeled Dₐ₁, Dₐ₂, D_{b1}, D_{b2}, D_{c1}, and D_{c2} while the IGBTs of FIG. 3 are respectively labeled Sₐ₁, Sₐ₂, S_{b1}, S_{b2}, S_{c1}, and S_{c2}. The power switches Sₐ₁, Sₐ₂, Dₐ₁, and Dₐ₂ are part of phase leg A of the three-phase converter, which is labeled as the first phase leg a 316 in FIG. 3. Similarly, the power switches S_{b1}, S_{b2}, D_{b1}, and D_{b2} are part of phase leg B 318 and the power switches S_{c1}, S_{c2}, D_{c1}, and D_{c2} are part of phase leg C 320 of the three-phase converter. The inverter may include any number of the power switches 302 or circuit elements depending on the particular configuration of the inverter.

As illustrated in FIG. 3, current sensors CSₐ, CS_{b}, and CS_{c} are provided to sense current flow in the respective phase legs 316, 318, 320. FIG. 3 shows the current sensors CSₐ, CS_{b}, and CS_{c} separate from the PEM 126. However, current sensors CSₐ, CS_{b}, and CS_{c} may be integrated as part of the PEM126 depending on its configuration. Current sensors CSₐ, CS_{b}, and CS_{c} of FIG. 3 are installed in series with each of phase legs A, B and C (i.e., phase legs 316, 318, 320 in FIG. 3) and provide the respective feedback signals iₐₛ, i_{bs}, and i_{cs} (also illustrated in FIG. 3) for the system 300. The feedback signals iₐₛ, i_{bs}, and i_{cs} may be raw current signals processed by logic device (LD) 310 or may be embedded or encoded with data or information about the current flow through the respective phase legs 316, 318, 320. Also, the power switches 302 (e.g., IGBTs) may include current sensing capability. The current sensing capability may include being configured with a current mirror output, which may provide data/signals representative of iₐₛ, i_{bs}, and i_{cs}. The data/signals may indicate a direction of current flow, a magnitude of current flow, or both the direction and magnitude of current flow through the respective phase legs A, B, and C.

Referring again to FIG. 3, the system 300 includes a logic device (LD) or controller 310. The controller or LD 310 can be implemented by various types or combinations of electronic devices and/or microprocessor-based computers or controllers. To implement a method of controlling the PEM 126, the controller 310 may execute a computer program or algorithm embedded or encoded with the method and stored in volatile and/or persistent memory 312. Alternatively, logic may be encoded in discrete logic, a microprocessor, a microcontroller, or a logic or gate array stored on one or more integrated circuit chips. As shown in the embodiment of FIG. 3, the controller 310 receives and processes the feedback signals iₐₛ, i_{bs}, and i_{cs} to control the phase currents iₐ, i_{b}, and i_{c} such that the phase currents iₐ, i_{b}, and i_{c} flow through the phase legs 316, 318, 320 and into the respective windings of the electric machine 114 according to various current or voltage patterns. For example, current patterns can include patterns of phase currents iₐ, i_{b}, and i_{c} flowing into and away from the DC-bus 304 or a DC-bus capacitor 308. The DC-bus capacitor 308 of FIG. 3 is shown separate from the PEM 126. However, the DC-bus capacitor 308 may be integrated as part of the PEM 126.

As shown in FIG. 3, a storage medium 312 (hereinafter “memory”), such as computer-readable memory may store the computer program or algorithm embedded or encoded with the method. In addition, the memory 312 may store data or information about the various operating conditions or components in the PEM 126. For example, the memory 312 may store data or information about current flow through the respective phase legs 316, 318, 320. The memory 312 can be part of the controller 310 as shown in FIG. 3. However, the memory 312 may be positioned in any suitable location accessible by the controller 310.

As illustrated in FIG. 3, the controller 310 transmits at least one control signal 236 to the power converter system 126. The power converter system 126 receives the control signal 322 to control the switching configuration of the inverter and therefore the current flow through the respective phase legs 316, 318, and 320. The switching configuration is a set of switching states of the power switches 302 in the inverter. In general, the switching configuration of the inverter determines how the inverter converts power between the DC power link 306 and the electric machine 114.

To control the switching configuration of the inverter, the inverter changes the switching state of each power switch 302 in the inverter to either an ON state or an OFF state based on the control signal 322. In the illustrated embodiment, to switch the power switch 302 to either ON or OFF states, the controller/LD 310 provides the gate voltage (Vg) to each power switch 302 and therefore drives the switching state of each power switch 302. Gate voltages Vgₐ₁, Vgₐ₂, Vg_{b1}, Vg_{b2}, Vg_{c1}, and Vg_{c2} (shown in FIG. 3) control the switching state and characteristics of the respective power switches 302. While the inverter is shown as a voltage-driven device in FIG. 3, the inverter may be a current-driven device or controlled by other strategies that switch the power switch 302 between ON and OFF states. The controller 310 may change the gate drive for each IGBT based on the rotational speed of the electric machine 114, the mirror current, or a temperature of the IGBT switch. The change in gate drive may be selected from a plurality of gate drive currents in which the change gate drive current is proportional to a change in IGBT switching speed.

As also shown in FIG. 3, each phase leg 316, 318, and 320 includes two switches 302. However, only one switch in each of the legs 316, 318, 320 can be in the ON state without shorting the DC power link 306. Thus, in each phase leg, the switching state of the lower switch is typically opposite the switching state of the corresponding upper switch. Consequently, a HIGH state of a phase leg refers to the upper switch in the leg in the ON state with the lower switch in the OFF state. Likewise, a LOW state of the phase leg refers to the upper switch in the leg in the OFF state with the lower switch in the ON state. As a result, IGBTs with current mirror capability may be on all IGBTs, a subset of IGBTs (e.g., Sₐ₁, S_{b1}, S_{c1}) or a single IGBT.

Two situations can occur during an active state of the three-phase converter example illustrated in FIG. 2: (1) two phase legs are in the HIGH state while the third phase leg is in the LOW state, or (2) one phase leg is in the HIGH state while the other two phase legs are in the LOW state. Thus, one phase leg in the three-phase converter, which may be defined as the “reference” phase for a specific active state of the inverter, is in a state opposite to the other two phase legs, or “non-reference” phases, that have the same state. Consequently, the non-reference phases are either both in the HIGH state or both in the LOW state during an active state of the inverter.

FIG. 4 is an examplary graphical representation of a profile 400 of a gate current 404 of an IGBT with respect to time 402. In this example, the IGBT is a N-channel enhancement mode IGBT, however the invention is not limited to this device. Here, the profile 400 includes high current gate drive (I_{g1}) that results in an increase in the voltage of the gate of the IGBT (Vge) 404. When Vge is equal to a threshold gate voltage 406 (Vₜₕ), the IGBT turns on at time 410. The gate current (I_{g1}) is substantially maintained until the gate voltage (Vge) crosses the Miller plateau 408 at time 412. After reaching the Miller plateau 408, the gate voltage will peak 414 and settle at the miller plateau voltage to a point 416 at which the gate voltage 404 increases to the maximum gate voltage at point 418. The freewheeling diode has a diode current 420. Typically during operation, when the IGBT is turned off, the freewheeling diode is forward biased and flows current through the diode until the gate voltage 404 applied to the IGBT increases to the threshold voltage 406 at time 410, at which time the current flow through the IGBT reduces the current flow through the diode and the diode current 420 is reduced. The diode current 420 continues to decrease and at time 412 the diode current changes direction from a positive current to a negative current. The diode current 420 will continue to decrease to peak negative current 424 after which, the current will settle to zero. The negative current of the diode is during the diode's reverse recovery time. A charge flowing during a reverse recovery time, called a reverse recovery charge, must be recaptured prior to the diode shutting off. When switching from the conducting to the blocking or shut off state, the reverse recovery charge must be a recaptured before the diode blocks the reverse current.

As the diode current 420 is forward biased and flowing current, the IGBT collector current 426 is turned off. The IGBT collector current 426 is turned off until the gate voltage 404 reaches the threshold voltage 406, at which point the IGBT will begin to flow a collector current 426. The collector current 426 is based on the gate voltage 404 and the transconductance of the IGBT. Associated with the diode current 420, the diode voltage 428 starts out low, namely a forward voltage drop across the diode, and then increases such that the diode voltage 428 peaks slightly after the peak negative current 424 occurs. The operation of the IGBT and application of Vge is to reduce the diode voltage peak as a peak exceeding the diode's maximum voltage may damage the diode.

FIG. 4 illustrates IGBT turn on transient for an automotive system divided into 4 stages, Stage I-IV.

In stage I, the gate voltage 404 ramps from 0 to the threshold voltage 406 (Vth) The threshold voltage is typically 5-7 V. During this stage, the IGBT collector current 426 (Ic) is approximately equal to 0. Typically, a freewheeling diode associated with the IGBT is forward biased and has a diode current 420 (Id) at a steady state on current, for example in a hybrid vehicle inverter the current may be approximately 300 A. The gate drive during stage I may be designed to provide maximum current to reduce a delay time between a gate drive ON signal and an IGBT gate response.

In stage II, the gate voltage 404 exceeds a gate voltage threshold (Vth) and the IGBT current 426 starts to ramp up. The gate voltage 404 in stage II increases from Vth 406 to the miller plateau voltage 408. As the gate voltage 404 increases, the IGBT collector current 426 (Ic) ramps from 0 and the diode current 420 decreases from steady state on current to 0. The gate drive in stage II may be designed to provide maximum current to reduce transient time and losses.

In stage III, the IGBT collector current 426 increases passed the steady state on current and diode current 420 transitions from a positive current to a negative current. This is referred to as a diode reverse recovery state. The diode voltage 428 increases quickly and increases past the dc bus voltage, for example in a hybrid vehicle inverter the voltage may be approximately 400 V. If the diode voltage 428 peaks at a voltage higher than either the IGBT breakdown voltage or the diode breakdown voltage, the IGBT or diode could get damaged. The gate drive should provide small current to slow down the diode reverse recovery and avoid diode overvoltage.

In stage IV, the diode is fully recovered from the reverse recovery effect and the IGBT gate voltage continue rise to 15V.

FIG. 5 is a graphical representation of MOSFET characteristic curves 500 illustrating a MOSFET drain current (Id) 502 with respect to drain to source voltage (Vds) 504 at a plurality of gate voltages 506. The gate voltages 506 are shown as the difference of the gate to source voltage (Vgs) minus the threshold voltage (Vth). The gate voltage (Vgs) above the threshold voltage (Vth) is also referred to as gate voltage above threshold (Vgt) For an enhancement mode MOSFET, the threshold voltage is a minimum gate-to-source voltage differential needed to create a conducting path between the source and drain terminals of the MOSFET. The MOSFET does not conduct at gate voltages less than the Vth. The first operating state of a MOSFET is called cutoff and is when the gate voltages less than the Vth and the MOSFET is not conducting. When viewing the characteristic curves 500 of a MOSFET, a transitional line 508 is shown as the point in which the drain to source voltage (Vds) is equal to the Vgs−Vth. When the gate voltage is greater than Vth and the drain to source voltage (Vds) is greater than Vgs−Vth, the MOSFET is operating in a saturation region, this is also known as a saturation mode of operation. Traditionally, when the gate voltage is greater than Vth and the drain to source voltage (Vds) is less than Vgs−Vth, the MOSFET is considered to be operating in a linear region. However, the linear region may be divided into along another line, the sub-linear transition line 510. The sub-linear transition line 510 is the point at which the drain current of the MOSFET is equal to a constant multiplied by Vds and Vgt. When operating in the linear region in which Vds is much less than Vgt, the characteristic is that the operation is in a true linear region and for larger Vds in which the operation is between the sub-linear transition line 510 and the transitional line 508, the operation is in a sub-linear region. Here, selection of the MOSFET is done such that the as the IGBT gate voltage rises, the Vds of the MOSFET decreases, so initially, the MOSFET is turned on in a saturation region allowing for maximum current. As the IGBT gate voltage rises, the MOSFET Vds decreases such that Vds crosses the transition line 508 as the current flow through the freewheeling diode switches from positive to negative. This limits the current flow to the gate of the IGBT and softens the turn on to reduce the diode overshoot.

In an alternative embodiment, selection of the MOSFET is done such that as the IGBT gate voltage rises, the MOSFET Vds decreases so that the Vds crosses the sub-transition line 510 as the current flow through the freewheeling diode switches from positive to negative.

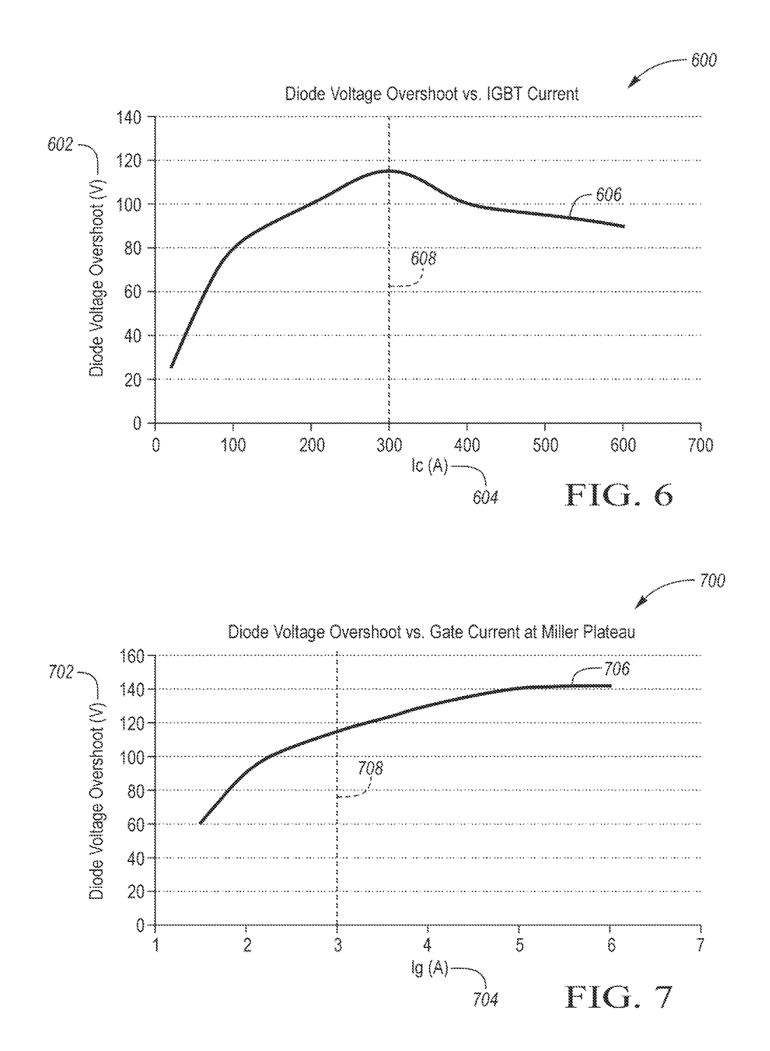

FIG. 6 is a graphical representation 600 of diode voltage 602 (Vd) with respect to IGBT collector current 604 (Ic). Based on test results, the profile 606 of the diode voltage 602 (Vd) overshoot vs. Ic 604 at a constant gate current (e.g., 3 A) and during operation in a harsh environment (e.g., Temperature=−25 C, dc bus voltage=400V) is shown. This graph 600 shows that when the IGBT current 604 is 300 A 608, the diode voltage overshoot reaches a peak voltage of 115V. In this condition, the peak diode voltage could reach 400V+115V=515V during the diode's reverse recovery.

FIG. 7 is a graphical representation 700 of diode voltage (Vd) 702 with respect to IGBT gate current 704 (Ig). This graphical representation 700 shows a trend 706 of Vd 702 overshoot vs. Ig 704 during operation in a harsh environment (e.g., Ic=300 A, Temp=−25 C, dc bus voltage=400V). It shows that as the gate current 704 increases, the IGBT switching speed increases and the diode reverse recovery is faster. If the diode specification determines a max voltage cannot be higher than 515V at any conditions, then a maximum gate current may need to be limited to only 3 A 708 during the reverse recovery.

From the analysis above, it is not desirable for diode reverse recovery when Ic=300 A and the gate current is greater than 3 A. From the above figures, it is desirable that the gate current be less than 3 A during the reverse recovery. This provides a guideline for selecting a MOSFET.

Below is an exemplary table of a transfer curve of an IGBT.

| Ic (Amperes) | Vge (Volts) |
|---|---|
| 1 | 7 |
| 10 | 8 |
| 100 | 9 |
| 300 | 10.5 |
| 450 | 11 |
| 600 | 12 |

From the data of the IGBT transfer curve, a MOSFET and IGBT combination may be determined based on the corresponding miller plateau voltage at Ic=300 A in which Vge=10.5V @ Ic=300 A.

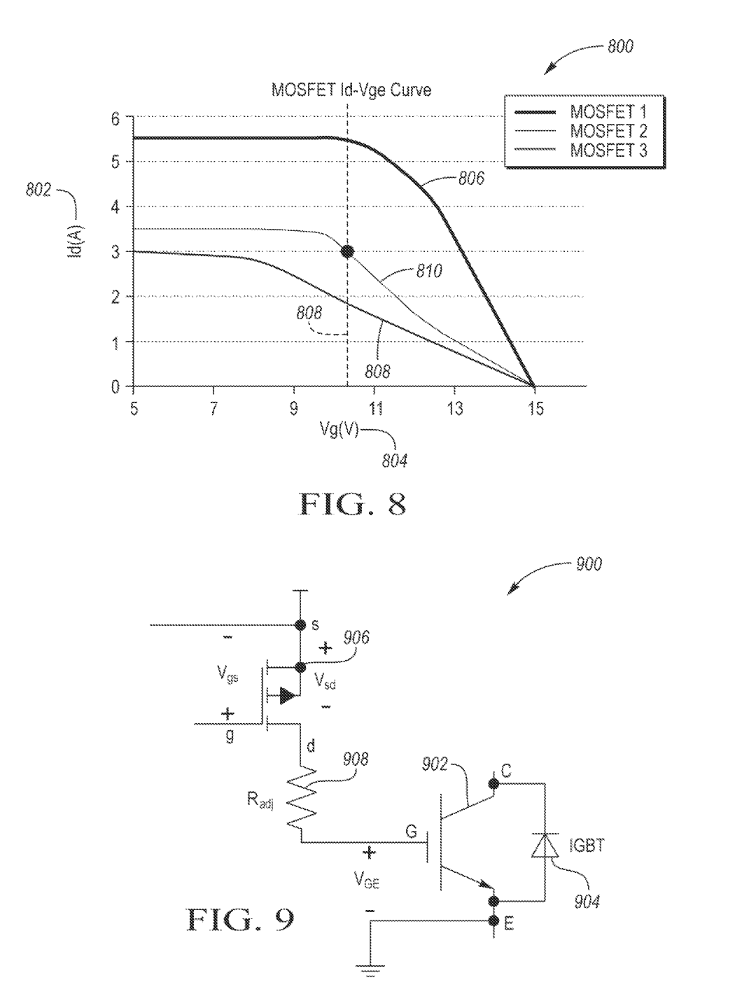

FIG. 8 is a graphical representation 800 of a MOSFET drain current 802 (Id) with respect to IGBT gate voltage 804 (Vge). The MOSFET drain current 802 vs. Vge 804 curve may be used to select a MOSFET. For example, FIG. 8 illustrates the response of three different MOSFETs. MOSFET 1's response 806, MOSFET 2's response 808 and MOSFET 3's response 810. Here MOSFET 2 and MOSFET 3 satisfied the requirement 812 and MOSFET 1 does not. When choosing between MOSFET 2 and MOSFET3, the fact that MOSFET 2 has higher current at a small Vg, it may be advantageous to select MOSFET 2.

FIG. 9 is a schematic diagram 900 of a MOSFET 906 coupled with an IGBT 902 to control the gate voltage of the IGBT 902. The IGBT typically has an emitter, a gate, and a collector, however some IGBTs are configured with multiple elements such as an IGBT with dual emitters. The use of dual emitters allows for a current mirror configuration in which current flowing through one of the emitters may be determined based on current flow in the other emitter. Coupled with the IGBT 902 is a freewheeling diode 904. The freewheeling diode 904 may also be referred to as a flyback diode or a clamp diode. The freewheeling diode 904 may be integrated monolithically with the IGBT 902, the diode 904 may be discrete from the IGBT 902 and housed in a separate package, or housed in the same package as the IGBT 902. The diode 902 is oriented such that the anode of the diode 904 is coupled with the emitter of an N-channel IGBT. The MOSFET 906 also referred to as a Metal Oxide Semiconductor Field Effect Transistor, may be an enhancement mode FET, a depletion mode FET, or a Junction Field Effect Transistor (JFET). A depletion mode FET and JFET operate different from an enhancement mode FET, an enhancement mode FET does not conduct absent a gate voltage and requires a gate voltage to enhance the channel so that the device will form a conducting channel between the drain and source. A depletion mode FET has a conducting channel between the drain and source. The JFET and depletion mode transistor require a voltage on the gate to pinch off the channel and stop conducting between the drain and source. The use of a JFET or a depletion mode FET requires the gate drive to work opposite the enhancement mode FET. Also, as these components have a conductive channel when no gate voltage is applied, care must be exercised to reduce the risk of a high-side and low-side device being on at the same time. The circuit 900 may also include an external gate resistor 908. The gate resistor may limit the current flow onto the gate of the IGBT 902. Further, the gate voltage of the MOSFET may be lower than the normal on-state gate voltage so that the MOSFET is operated in the linear region.

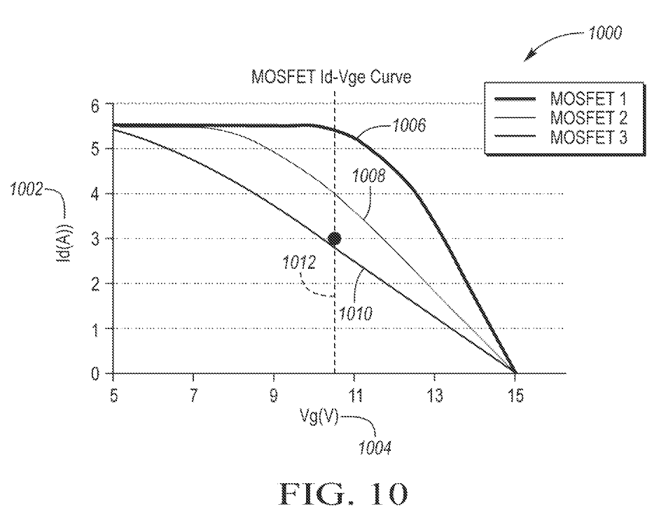

FIG. 10 is a graphical representation 1000 of a MOSFET drain current 1002 (Id) with respect to an IGBT gate voltage 1004 (Vge). Here, a single MOSFET is selected to drive an IGBT, and the response is provided based on varying values of a gate resistor (Radj) such as gate resistor 908. Here, Radj is shown to shift the MOSFET Id-Vge curve. FIG. 10 graphically illustrates the response of MOSFET 1 from FIG. 8 with different Radj. It is illustrated that adding Radj=1.0 Ohm when using MOSFET 1 satisfied the requirement, even when the original MOSFET 1 does not satisfy the requirement. Likewise, the use of Radj=0.5 Ohm does not meet the requirement.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as Read Only Memory (ROM) devices and information alterably stored on writeable storage media such as floppy disks, magnetic tapes, Compact Discs (CDs), Random Access Memory (RAM) devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes may include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A vehicle comprising:
an inverter including an N-channel IGBT, with a freewheeling diode, coupled to a phase of an electric machine, and having a MOSFET coupling a local voltage with a gate of the IGBT and configured to transition from saturation to linear operation as a current flow direction through the diode switches from positive to negative while the IGBT initiates a current through the electric machine.

2. The vehicle of claim 1 further including a gate resistor coupled between the gate of the IGBT and the MOSFET.

3. The vehicle of claim 2, wherein the resistance of the resistor is selected to limit a drain current of the MOSFET to a predetermined threshold for an associated gate voltage of the IGBT.

4. The vehicle of claim 1, wherein the MOSFET is a P-channel MOSFET.

5. The vehicle of claim 1 further including a charge pump circuit to output a MOSFET gate voltage greater than the local voltage to turn-on the MOSFET, and wherein the MOSFET is an N-channel MOSFET.

6. A vehicle DC-DC converter comprising:
an inductor;
an N-channel charge IGBT with a freewheeling diode coupled between a terminal of the inductor and a local ground; and
a charge MOSFET coupling a local voltage with a gate of the charge IGBT, and configured to transition from saturation to linear operation as a current flow direction in the diode switches from positive to negative while the IGBT initiates a current through the inductor.

7. The converter of claim 6 further including a N-channel pass IGBT having a freewheeling pass diode coupled between the terminal of the inductor and an output terminal, and a pass MOSFET coupling a local pass voltage with a pass gate of the pass IGBT, wherein the MOSFET is configured to transition from saturation to linear operation as a direction of current flow in the pass diode switches from positive to negative while the pass IGBT initiates an output current through an electric machine coupled with the output terminal.

8. The vehicle of claim 7, wherein the current is based on inductance of a phase of the electric machine, a bus voltage, and a rotational speed of the electric machine.

9. A power electronics module for a vehicle comprising:
an N-channel IGBT having an emitter, gate, and collector;
a freewheeling diode coupled parallel with the IGBT; and
a MOSFET coupling a local voltage with the IGBT gate and configured to transition from saturation to linear operation as a direction of current flowing through the diode reverses from positive to negative while the IGBT turns on.

10. The vehicle of claim 9 further including a gate resistor coupled between the gate of the IGBT and the MOSFET.

11. The vehicle of claim 10, wherein the resistance of the resistor is selected to limit a drain current of the MOSFET to a predetermined threshold for an associated gate voltage of the IGBT.

12. The vehicle of claim 9, wherein the MOSFET is a P-channel MOSFET.

13. The vehicle of claim 9 further including a charge pump circuit to output a MOSFET gate voltage greater than the local voltage to turn-on the MOSFET, and wherein the MOSFET is an N-channel MOSFET.
